(19) United States
(12) Patent Application Publication
(10) Pub. No.: US 2022/0189749 A1
(43) Pub. Date: Jun. 16, 2022

(54) Process Kit Conditioning Chamber

(71) Applicant: Applied Materials, Inc., Santa Clara, CA (US)

(72) Inventors: Ribhu Gautam, Singapore (SG); Vibhu Jindal, San Jose, CA (US); Kamatchi Gobinath Manoharan, Tiruppur (IN); Sanjay Bhat, Singapore (SG); Praveen Kumar Choragudi, Andhra Pradesh (IN); Wen Xiao, Singapore (SG); Vinodh Ramachandran, Singapore (SG)

(73) Assignee: Applied Materials, Inc., Santa Clara, CA (US)

(21) Appl. No.: 17/120,721

(22) Filed: Dec. 14, 2020

(51) Int. Cl. H01J 37/32; C23C 14/34

(52) U.S. Cl. CPC H01J 37/32853; H01J 2237/022; C23C 14/34; H01J 37/32532

(57) ABSTRACT

An ex situ physical vapor deposition (PVD) process kit conditioning apparatus configured to condition process kit components of a PVD substrate processing chamber, the ex situ PVD process kit conditioning apparatus comprising a chamber assembly, a central cathode assembly configured to mount one or more targets. The apparatus is configured to receive one or more components of a process kit of a PVD substrate processing chamber and the central cathode assembly is positioned and configured so that the apparatus deposits the defect reduction coating substantially uniformly on an inner surface of a process kit component of the PVD substrate processing chamber.

### TECHNICAL FIELD

The present disclosure generally relates to conditioning chambers for process kits. In particular, the present disclosure is directed to an ex-situ, standalone conditioning chambers for conditioning process kits of physical vapor deposition chambers.

### BACKGROUND

Conventional physical vapor deposition (PVD) substrate processing chambers deposit a variety of materials such as metal layers and dielectric layers. For example, PVD substrate processing chambers are utilized in the manufacture of extreme ultraviolet (EUV) mask blanks, and multiple alternating layers of Si and Mo are deposited on a substrate to form a multilayer reflective stack on the substrate. Additional layers such a planarization layer, a capping layer, and absorber layer and an antireflective layer may be deposited on the substrate in the PVD substrate processing chamber. PVD substrate processing chambers are often sensitive to contamination, and in particular, EUV mask blanks are one example of a product manufactured in a PVD substrate processing chamber that is sensitive to particulate contamination. More specifically, EUV mask blanks have a low tolerance for defects on the working area of the EUV mask blank. Particulate contaminants in the working area of the mask blank are difficult to repair and tend to prevent production of a functioning EUV mask blank

During manufacture of an EUV mask blank, a substrate is positioned on a support surface within a PVD substrate processing chamber. Because deposition occurs both on the substrate and the surrounding surface area of the processing chamber, conventional PVD substrate processing chambers utilize a process kit comprising interchangeable parts, which are commonly either discarded or cleaned within the PVD substrate processing chamber itself in-situ, removing deposition particles from the process kit. Hydrocarbon contaminants and residual particles formed on the process kits of PVD substrate processing chambers are major defect sources on products made in PVD substrate processing chambers, such as EUV mask blanks manufactured in multi-cathode PVD substrate processing chambers.

The conditioning of process kit components commonly includes deposition of a conditioning layer on the process kit components using the same PVD substrate processing chamber used to make products such as EUV mask blanks, which renders the PVD substrate processing chamber unavailable for product manufacturing operation. Conditioning the process kit components in the same PVD substrate processing chamber used to manufacture products such as EUV mask blanks before starting a deposition process to manufacture the product can take four to five days, which significantly reduces time available for the PVD substrate processing chamber to be used to manufacture product.

Furthermore, because the layout and dimensions of conventional PVD substrate processing chambers are optimized for the deposition of layers on substrates and not for forming a conditioning layer on the process kit components, achieving a uniform conditioning layer on the process kit components in same PVD substrate processing chamber used to make product results in an increase in down-time of the PVD substrate processing chamber and generation of increased defects during processing of substrates.

Therefore, there exists a need for apparatus and methods that provide improved process kit conditioning and reduced downtime of PVD substrate processing chambers.

### SUMMARY

One aspect of the present disclosure pertains to an ex situ physical vapor deposition (PVD) process kit conditioning apparatus configured to condition process kit components of a PVD substrate processing chamber. The ex situ PVD process kit conditioning apparatus comprises a chamber assembly comprising a chamber floor, a chamber housing and a chamber upper plate, the chamber upper plate having one or more openings configured to expose one or more targets, the conditioning apparatus configured to deposit a defect reduction coating, the chamber housing and chamber upper plate defining a conditioning volume configured to receive process kit components from the PVD substrate processing chamber; and a central cathode assembly configured to mount the one or more targets, wherein upon positioning of the process kit components within the conditioning volume of the ex situ PVD process kit conditioning apparatus, the central cathode assembly is positioned and configured so that apparatus deposit the defect reduction coating substantially uniformly on an inner surface of the process kit components of the PVD substrate processing chamber, at least one of the process kit components having a sloped wall and a concave inner surface.

Another aspect of the disclosure pertains to a method of conditioning one or more process kit components of a physical vapor deposition (PVD) substrate processing chamber. The method comprises removing the one or more process kit components from the PVD substrate processing chamber, the one or more process kit components of the PVD substrate processing chamber including a chamber liner including an inner surface having a sloped wall and a concave inner surface and a rotatable shield including an inner surface having concave surface; placing the one or more process kit components removed from the PVD substrate processing chamber in a separate, ex-situ PVD process kit conditioning apparatus comprising a central cathode assembly positioned and configured so that the apparatus deposits a substantially uniform defect reduction coating on the inner surface of the one or more process kit components; and depositing a substantially uniform defect reduction coating on the inner surface of the one or more process kit components.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross-sectional view of a conventional PVD substrate processing chamber;

FIG. 2 is a cross-sectional view of ex situ physical vapor deposition (PVD) process kit conditioning apparatus according to one or more embodiments;

FIG. 3 is a cross-sectional view of an ex situ physical vapor deposition (PVD) process kit conditioning apparatus according to one or more embodiments;

FIG. 4 is a top view of an ex situ physical vapor deposition (PVD) process kit conditioning apparatus according to one or more embodiments;

FIG. 5A is a top view of an ex situ physical vapor deposition (PVD) process kit conditioning apparatus according to one or more embodiments;

FIG. 5B is a top view of an ex situ physical vapor deposition (PVD) process kit conditioning apparatus according to one or more alternative embodiments; and,

FIG. 6 is a flow chart showing steps of a method 300 of cleaning components of a PVD substrate processing chamber according to one or more embodiments;

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “horizontal” as used herein is defined as a plane parallel to the plane or surface of a mask blank, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” indicates that there is direct contact between elements. The term “directly on” indicates that there is direct contact between elements with no intervening elements.

Those skilled in the art will understand that the use of ordinals such as “first” and “second” to describe process regions do not imply a specific location within the processing chamber, or order of exposure within the processing chamber.

According to one or more embodiments, the phrase “ex situ” and the word standalone refer to an apparatus, a chamber or a process that is outside the PVD substrate processing chamber environment. For example, an ex situ physical vapor deposition (PVD) process kit conditioning apparatus or a standalone physical vapor deposition (PVD) process kit conditioning apparatus is an apparatus that is separated from the PVD substrate processing chamber, or in a separate location from the PVD substrate processing chamber and outside the PVD substrate processing chamber. In some embodiments, the PVD substrate processing chamber may be part of a cluster tool or a connected cluster of substrate processing chambers which may include additional PVD substrate processing chambers, chemical vapor deposition substrate processing chambers, atomic layer deposition substrate processing chambers, cleaning chambers, etching chambers, annealing chambers, and other substrate processing chambers. However, an ex situ physical vapor deposition (PVD) process kit conditioning apparatus or a standalone physical vapor deposition (PVD) process kit conditioning apparatus is not connected to or part of a cluster tool that includes the PVD substrate processing chamber environment.

References to PVD substrate processing chambers and methods or “conventional PVD substrate processing chambers” described herein are directed to conventional substrate processing chambers and methods for the manufacture of extreme ultraviolet (EUV) mask blanks and other substrates. However, an ex situ physical vapor deposition (PVD) process kit conditioning apparatus (or chamber) is not configured for the processing of substrates or the deposition of the layers on substrates. Instead, an ex situ PVD process kit conditioning apparatus or chamber has a cathode assembly positioned and configured with respect to an interior volume to provide a substantially uniform coating on a process kit component. An “EUV mask blank” is an optically flat structure used for forming a reflective mask having a mask pattern. In one or more embodiments, the reflective surface of the EUV mask blank forms a flat focal plane for reflecting the incident light, such as the extreme ultraviolet light. An EUV mask blank comprises a substrate providing structural support to an extreme ultraviolet reflective element such as an EUV reticle. In one or more embodiments, the substrate is made from a material having a low coefficient of thermal expansion (CTE) to provide stability during temperature changes. The substrate according to one or more embodiments is formed from a material such as silicon, glass, oxides, ceramics, glass ceramics, or a combination thereof.

An EUV mask blank includes a multilayer stack, which is a structure that is reflective to extreme ultraviolet light. The multilayer stack includes alternating reflective layers of a first reflective layer and a second reflective layer. The first reflective layer and the second reflective layer form a reflective pair. In a non-limiting embodiment, the multilayer stack includes a range of 20-60 of the reflective pairs for a total of up to 120 reflective layers.

The first reflective layer and the second reflective layer can be formed from a variety of materials. In an embodiment, the first reflective layer and the second reflective layer are formed from silicon and molybdenum, respectively. The multilayer stack forms a reflective structure by having alternating thin layers of materials with different optical properties to create a Bragg reflector or mirror. The alternating layer of, for example, molybdenum and silicon can be formed by physical vapor deposition, for example, in a multi-cathode source chamber. An absorbing layer made from a material that absorbs EUV radiation, such as a tantalum-containing material (e.g., TaN or TaON) can also be formed by physical vapor deposition utilizing the chambers and methods described herein. Conventional methods comprise depositing alternating layers of a multilayer reflector material by sputtering material from a target on a substrate in a multi-cathode physical vapor deposition chamber, the substrate placed within an inner volume of the physical vapor deposition chamber defined by a chamber wall, the inner volume including an upper section, a lower section and a central region, and the substrate surrounded by a shield surrounding the central region, the shield having an inner surface, an upper portion and a lower portion. The method further comprises laterally deflecting particles generated during the sputtering with an electric field generated at the upper portion of the shield to prevent particles from being deposited in the substrate; and generating a magnetic field at a lower portion of the shield to prevent particles from being deposited on the substrate.

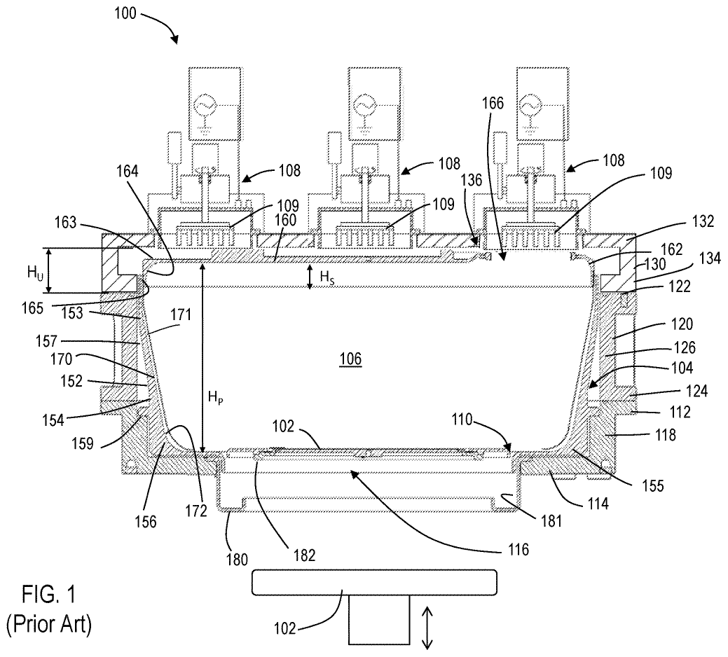

A conventional PVD substrate processing chamber 100 is depicted in FIG. 1, in which a side view of a portion of the conventional PVD substrate processing chamber 100 is shown. The conventional PVD substrate processing chamber comprises a chamber floor 110, a chamber housing 120 and a chamber upper plate 130. The chamber floor 110 has a circular shape with an open top 112, a closed bottom 114 and sidewalls 118 therebetween. The chamber floor 110 further includes an opening 116 through which a substrate support 102 passes through. The chamber housing 120 has a cylindrical body with an open top 122, an open bottom 124 and sidewalls 126 therebetween. The chamber upper plate 130 has a cylindrical shape with a closed top 132 and an open bottom 134. The closed top 132 has one or more openings 136 for receiving a cathode assembly or one or more targets as explained in further detail below. In some embodiments, the chamber floor 110 and chamber housing 120 form a unitary body. In some embodiments, the chamber floor 110 and chamber housing 120 are separate components which, when assembled, are sealed with at least one O-ring or gasket positioned between the open top 112 of the chamber floor 110 and the open bottom 124 of the chamber housing 120. The chamber upper plate 130 is removably assembled with the chamber housing 120 to allow for the installation or removal of components of the process kit 150. When assembled, the chamber housing 120 and the chamber upper plate 130 are sealed with at least one O-ring or gasket positioned between the open top 122 of the chamber housing 120 and the open bottom 134 of the chamber upper plate 130.

The chamber floor 110, chamber housing 120 and chamber upper plate 130 define a chamber volume 104 in which one or more components of a process kit 150 are disposed within. As shown, the process kit 150 includes at least a chamber liner 152 having a bowl-shaped body 154 and a concave inner surface 156 and a rotatable shield 160 having a substantially cylindrical body 162 and an inner surface 164, which in some embodiments is a concave inner surface 164. As shown, the process kit 150 further includes an inner chamber liner 170 having a sloped wall 171 joined to an inner surface 172. The inner surface is concave. It will be appreciated that each of the inner surface 164 of the rotatable shield, the chamber liner 152 concave inner surface 156 and the inner surface 172 of the chamber liner have a concave surface, which includes a sloped surface and/or a curved surface. These concave surfaces included a sloped surface and/or a curved surface are not coated uniformly in the PVD substrate processing chamber 100 because the PVD substrate processing chamber 100 is configured to uniformly coat a substrate such as an EUV mask blank or wafer comprising a substantially flat surface placed on the substrate support. In some embodiments, the process kit 150 further includes an upper shield (not shown), a lower shield 180, a telescopic cover ring 182 and one or more intermediate shields (not shown). The lower shield 180 abuts the partially closed bottom 155 of the chamber liner 152.

The bowl-shaped body 154 of the chamber liner 150 has an open top 153 and an at least partially closed bottom 155, the at least partially closed bottom 155 in contact with the closed bottom 114 of the chamber floor 110. The rotatable shield 160 has an at least partially closed top 163 and an open bottom 165. The rotatable shield 160 has a height H_{S} defined by the closed top 163 and open bottom 165. The open top 153 of the chamber liner 152 creates a sealed environment with an open bottom 165 of the rotatable shield 160, the sealed environment defining the processing volume 106.

One or more components of the process kit 150 define a processing volume 106 in which deposition on a substrate occurs. The processing volume 106 is defined by the chamber liner 152 of the processing kit 150 and the rotatable shield 160 of the processing kit 150. A processing volume height H_{P} is defined from the partially closed bottom 155 of the chamber liner 152 to the partially closed top 163 of the rotatable shield 160. To accommodate the processing volume height H_{P}, the chamber upper plate 130 of the PVD substrate processing chamber has a height H_{U} and is sized such that the least partially closed top 163 of the rotatable shield 160 is in contact with the closed top 132 of the chamber upper plate.

The conventional PVD substrate processing chamber 100 is configured as a multi-cathode PVD substrate processing chamber including a multi-target PVD source configured to manufacture an MRAM (magnetoresistive random access memory) or a multi-target PVD source configured to manufacture an extreme ultraviolet (EUV) mask blank. At least one cathode assembly 108 is positioned over the one or more openings 136 of the chamber upper plate 130. In some embodiments, one or more targets 109 is positioned within the one or more openings 136 of the chamber upper plate 130. As shown, the one or more targets 109 is positioned within the one or more openings 136 of the chamber upper plate 130 and under the at least one cathode assembly 108 positioned over the one or more openings 136. The rotatable shield 160 of the process kit 150 is formed with the shield holes 166 so that the cathode assemblies 108 in some embodiments are used to deposit the material layers through the shield holes 166. Each of the cathode assemblies 108 is connected to a power supply (not shown) including direct current (DC) or radio frequency (RF).

The rotatable shield 160 is configured to expose one of the cathode assemblies 108 at a time and protect other cathode assemblies 108 from cross-contamination. The cross-contamination is a physical movement or transfer of a deposition material from one of the cathode assemblies 108 to another of the cathode assemblies 108. The one or more targets 109 in some embodiments are any suitable size. For example, each of the one or more targets 109 in some embodiments has a diameter in a range of from about 4 inches to about 20 inches, or from about 4 inches to about 15 inches, or from about 4 inches to about 10 inches, or from about 4 inches to about 8 inches or from about 4 inches to about 6 inches.

The substrate support 102 is configured to move vertically move up and down. As shown in FIG. 1, the substrate support 102 is in a lowered position. The lower shield 180 is sized and shaped to account for the travel of the substrate support 102 while still in the chamber.

When the material layers are sputtered, the materials sputtered from the one or more targets 109 in some embodiments are retained on the surfaces of the process kit 150 and not on the substrate alone, causing contamination of the components of the process kit 150 over time in the form of contaminant build up. To eliminate contaminants on the components of the process kit 150, the components of the process kit 150 are configured to be removable from the PVD substrate processing chamber 100 for conditioning. In some embodiments, the PVD substrate processing chamber 100 can be configured for conditioning, however, the dimensions of the PVD substrate processing chamber 100 are configured and optimized for deposition and not for conditioning of components of a process kit 150.

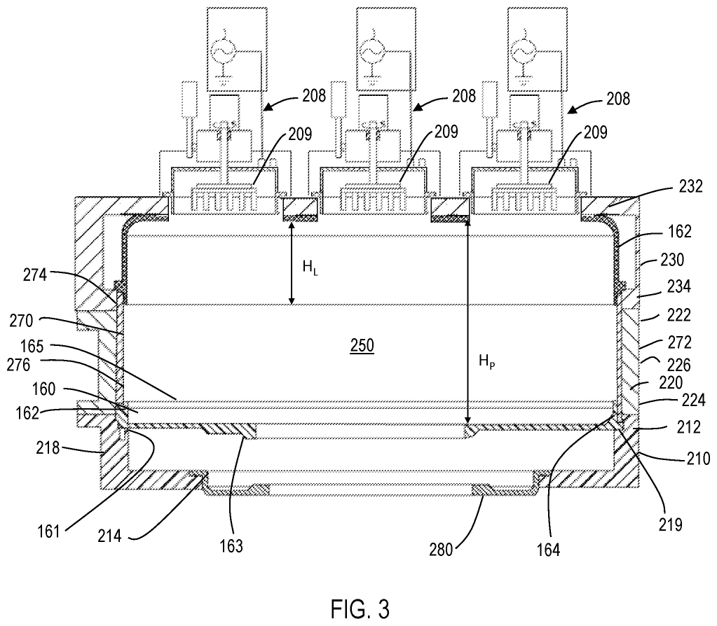

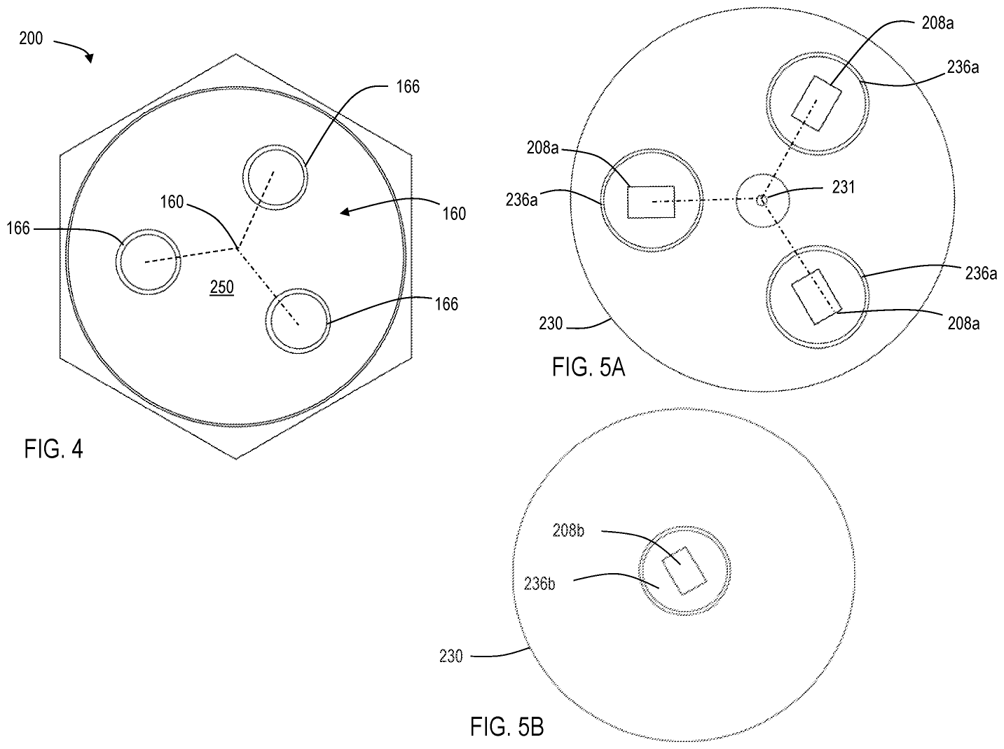

Embodiments of the disclosure pertain to an ex situ physical vapor deposition (PVD) process kit conditioning apparatus 200 configured to condition components of the PVD substrate processing chamber 100, and in particular one or more components of a process kit 150. FIG. 3 illustrates the PVD process kit conditioning apparatus 200 having the chamber liner 152 positioned within and FIG. 4 illustrates the PVD process kit conditioning apparatus 200 having the rotatable shield 160 disposed within. As explained in further detail below, the PVD process kit conditioning apparatus 200 is configured to optimally condition one or more components of a process kit 150 separate from the PVD substrate processing chamber 100.

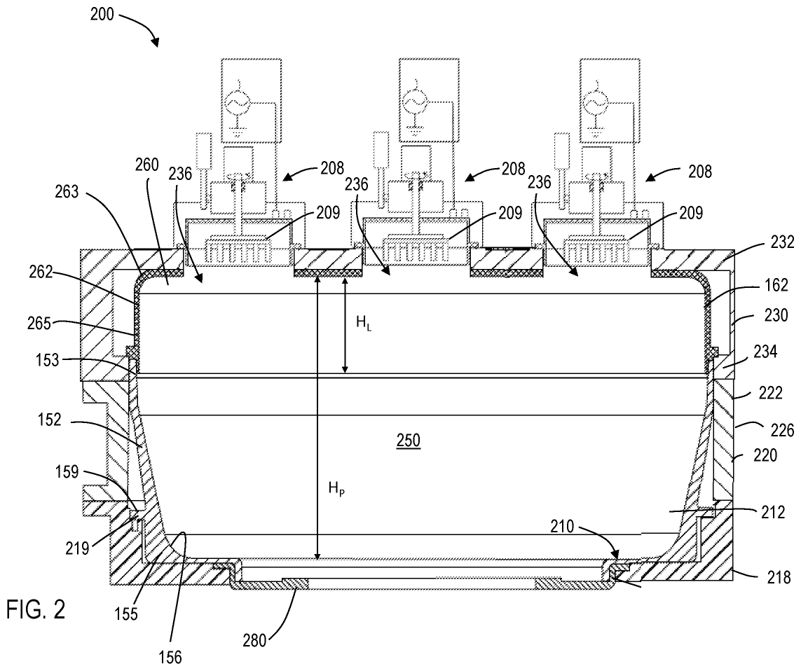

Referring now to FIGS. 2 and 3, the PVD process kit conditioning apparatus 200 comprises a chamber floor 210, a chamber housing 220 and a chamber upper plate 230. The chamber floor 210 has a circular shape with an open top 212, a closed bottom 214 and sidewalls 218 therebetween. According to one or more embodiments, the chamber floor 210 can comprise other shapes. The chamber floor 210 further includes an opening 216 through which a substrate support 202 passes through. The chamber housing 220 has a cylindrical body with an open top 222, an open bottom 224 and sidewalls 226 therebetween. The chamber upper plate 230 has a cylindrical shape with a closed top 232 and an open bottom 234. The closed top 232 has one or more openings 236 for receiving a cathode assembly or one or more target. In some embodiments, the chamber floor 210 and chamber housing 220 form a unitary body. In some embodiments, the chamber floor 210 and chamber housing 220 are separate components which, when assembled, are sealed with at least one O-ring or gasket positioned between the open top 212 of the chamber floor 210 and the open bottom 224 of the chamber housing 220. The chamber upper plate 230 is removably assembled with the chamber housing 220 to allow for the installation or removal of components of the process kit 150 for conditioning. When assembled, the chamber housing 220 and the chamber upper plate 230 are sealed with at least one O-ring or gasket positioned between the open top 222 of the chamber housing 220 and the open bottom 234 of the chamber upper plate 230.

The chamber floor 210, chamber housing 220 and chamber upper plate 230 define a conditioning volume 204 in which one or more components of a process kit 150 are disposed within. FIG. 2 illustrates the chamber liner 152 positioned within the conditioning volume 204. As shown, a bottom shield 280 is positioned within and in contact with an opening of the partially closed bottom 155 of the chamber liner 152 and the opening 216 of the chamber floor 210. A chamber lid 260 is positioned over and in contact with the open top 153 of the chamber liner 152. The chamber liner 152, the chamber lid 260 and the bottom shield 280 form a fluid-tight sealed conditioning region 250 for conditioning the concave inner surface 156 of the chamber liner 152. In some embodiments, the bottom shield 280 is replaced by the lower shield 180 of the process kit 150, allowing for the PVD process kit conditioning apparatus 200 to condition both the concave inner surface 156 of the chamber liner 152 and an inner surface 181 of the lower shield 180.

The chamber lid 260 has an at least partially closed top 263 and an open bottom 265. The chamber lid 260 has a height H_{L} defined by the closed top 263 and open bottom 265. The linear height H_{L} of the chamber lid 260 is greater than the linear height of the height H_{R} of the rotatable shield 160 of the PVD substrate processing chamber 100. This increased height H_{L} of the chamber lid 260 provides sufficient chamber height and volume to condition PVD substrate chamber process kit components as described further herein.

In some embodiments, the chamber lid 260 has one or more openings 268 which are aligned with the one or more openings 236 of the chamber upper plate 230. Stated differently, the one or more openings 268 of the chamber lid 260 are positioned under the one or more openings 236 of the chamber upper plate 230. In some embodiments, the chamber liner 152 further comprises a flange 159 extending from an outer surface 157 of the chamber liner 152. In some embodiments, the flange 159 is in contact with an inner ledge 219 of the chamber floor 210.

As shown in FIG. 3, in some embodiments, the rotatable shield 160 of the process kit 150 is flipped and positioned within the conditioning volume 204 of the PVD process kit conditioning apparatus 200. The rotatable shield 160 is flipped such that the concave inner surface 164 is conditioned by the PVD process kit conditioning apparatus 200. FIG. 4 illustrates a top view of the rotatable shield 160 flipped within the conditioning volume 204 of the PVD process kit conditioning apparatus 200. The shield holes 166 as illustrated are configured as three shield holes 166 positioned 120 degrees apart from a center axis 169 of the rotatable shield 160.

Referring back to FIG. 3, to create a fluid-tight seal between the rotatable shield 160 and the chamber lid 260, an intermediate liner 270 is positioned between the rotatable shield 160 and chamber lid 260. The intermediate shield 270 has a cylindrical body 272 with an open top 274 and an open bottom 276. The open top 274 of the intermediate liner 270 is adjacent to and in contact with the open bottom 265 of the chamber lid 260, forming a fluid tight seal. The open bottom 276 of the intermediate liner 270 is adjacent to and in contact with the open bottom 165 of the (flipped) rotatable shield 160. An outer peripheral edge 161 of the partially closed top 163 of the (flipped) rotatable shield 160 is adjacent to and in contact with the inner ledge 119 of the chamber floor 210.

In some embodiments, the PVD process kit conditioning apparatus 200 is configured as a multi-cathode PVD conditioning chamber. At least one cathode assembly 208 is positioned over the one or more openings 236 of the chamber upper plate 230. In some embodiments, a target assembly 209 is positioned within the one or more openings 236 of the chamber upper plate 230. In some embodiments, the target assembly 209 is positioned within the one or more openings 236 of the chamber upper plate 230 and under the at least one cathode assembly 208 positioned over the one or more openings 236. As best shown in FIG. 5A, in some embodiments the PVD process kit conditioning apparatus 200 is configured as a multi-cathode PVD conditioning chamber comprising two or more cathode assemblies 208a positioned over two or more openings 236 of the chamber upper plate 230. In some embodiments, each of the two or more cathode assemblies 208 and each of the over two or more openings 236 of the chamber upper plate 230 are positioned equally apart. In the embodiment show, the PVD process kit conditioning apparatus 200 has three cathode assemblies 208 positioned 120 degrees apart from a center axis 231 of the chamber upper plate 230. FIG. 5B shows a second embodiment of the chamber upper plate having a single, central cathode assembly 208b in a central opening 236 positioned on the center axis of the chamber upper plate 230. It will be appreciated that the center axis 231 is obscured or covered by the cathode assembly 208B.

Referring back to FIG. 3, in some embodiments, the chamber lid 260 is formed with one or more openings 236 so that the cathode assemblies 208 in some embodiments are used to deposit a deficit reduction coating through the one or more openings 268 of the chamber lid 260. Each of the cathode assemblies 208 is connected to a power supply (not shown) including direct current (DC) or radio frequency (RF). In some embodiments, the PVD process kit conditioning apparatus 200 further comprises at least one heating element. In some embodiments, the PVD process kit conditioning apparatus 200 further comprises a ring heater disposed below and adjacent to the chamber floor 210. The deficit reduction coating is sputter coated in a planar position opposite to the concave surfaces or inner surfaces of the one or more components of the target assembly 150. The height of linear height H_{L} of the chamber lid 260, and thus the linear distance between the target assembly 209 and the one or more components of the target assembly 209, is determinative of the quality of the deficit reduction coating. In some embodiments, the central cathode assembly 108 is positioned and configured such that the apparatus 200 is configured to deposit a substantially uniform defect reduction coating having a thickness that varies less than 50% over an entire inner surface of the components of the process kit 150. In one or more embodiments, the entire inner surface comprises one or more of a concave inner surface of a chamber liner, a concave inner surface of a chamber lid and a concave inner surface of a rotatable shield.

In some embodiments, the linear height H_{L} of the chamber lid 260 is 20% greater than the linear height of the height H_{R} of the rotatable shield 160 of the PVD substrate processing chamber 100. In some embodiments, the linear height H_{L} of the chamber lid 260 is at least 10% greater, 15% greater, 20% greater, or 25% greater than the linear height of the height H_{R} of the rotatable shield 160 of the PVD substrate processing chamber 100.

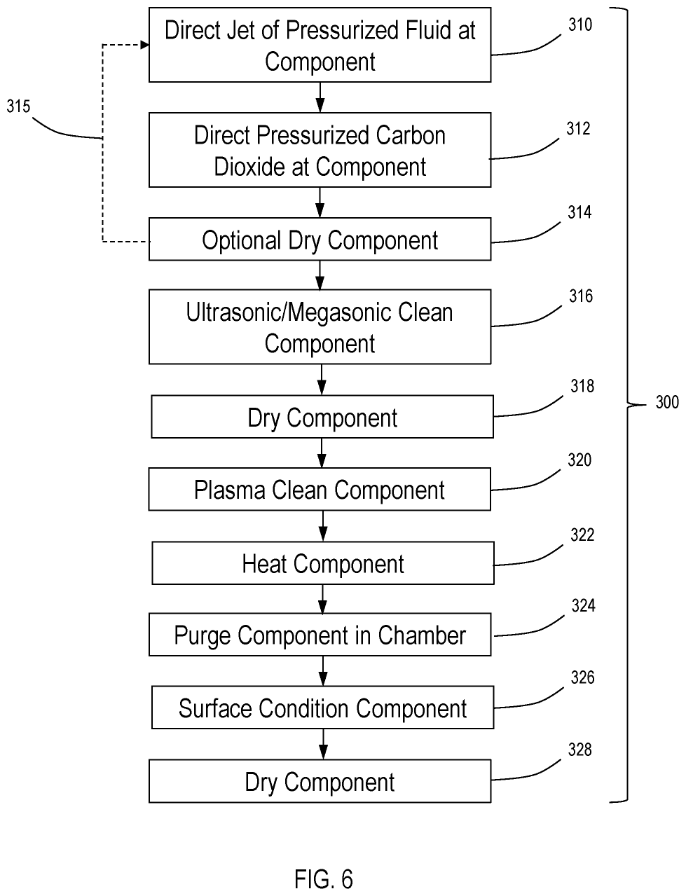

Referring now to FIG. 6, which is a flow chart showing a method 300 of cleaning components of a PVD substrate processing chamber 100 according to one or more embodiments of the disclosure. In one or more embodiments, the component of the process kit 150 from a PVD substrate processing chamber 100 are removed from the PVD substrate processing chamber 100 and cleaned according to methods described herein. The components of the process kit 150 are removed from the PVD substrate processing chamber 100 and placed in the PVD process kit conditioning apparatus 200, allowing for uninterrupted use of the PVD substrate processing chamber 100 and reducing down-time and maintenance of the PVD substrate processing chamber 100. Stated differently, conditioning of the components of the process kit 150 occurs in the PVD process kit conditioning apparatus 200. According to one or more embodiments of the method, by utilizing an a ex-situ process of conditioning process kit components, non-production time on PVD substrate processing chamber is reduced by at least 2, 3, 4 or 5 days. According to specific method embodiments, a method comprising utilizing a single separate, ex-situ PVD process kit conditioning apparatus for preparing 5, 6, 7, 8, 9, 10 or more treated process kits for PVD substrate processing chambers.

The method according to one or more embodiments comprises at 310 directing a jet of pressurized fluid at a surface of the component of the process kit 150. The method according to one or more embodiments further comprises at 312 directing pressurized carbon dioxide at the surface of the component of the process kit 150. The method according to one or more embodiments further comprises at 314 optionally drying the component of the process kit 150. The processes at 310, 312 and 314 may be repeated one to 10 times before proceeding to 316.

The method according to one or more embodiments further comprises at 316 placing the component of the process kit 150 in a liquid and producing ultrasonic waves in the liquid to further remove contaminants from the surface of the component of the process kit 150. Any suitable ultrasonic or megasonic cleaning apparatus can be used according to embodiments of the disclosure. The cleaning medium used in ultrasonic cleaning according to one or more embodiments comprises deionized water. The method according to one or more embodiments further comprises at 318 drying the component after 316. The method according to one or more embodiments further comprises at 320 using plasma to clean the surface of the component of the process kit 150. The method according to one or more embodiments further comprises at 322 subjecting the component of the process kit 150 to a thermal cycle by heating up to a peak temperature in a range of from at least 50° C. to about 40% of the component of the process kit 150 melting temperature and subsequently cooling the component of the process kit 150 to room temperature. In one or more embodiments, room temperature is 25° C. The method according to one or more embodiments further comprises at 324 placing the component of the process kit 150 in the PVD process kit conditioning apparatus 200, reducing the pressure in the PVD process kit conditioning apparatus 200 below atmospheric pressure and purging the process chamber with a gas. The method according to one or more embodiments further comprises at 326 surface conditioning the surface of the component of the process kit 150 by depositing a substantially uniform defect reduction coating on an surface of the component of the process kit 150. The method according to one or more embodiments further comprises at 328 drying the surface of the component of the process kit 150 by directing a gas on the surface of the component of the process kit 150. According to one or more embodiments of the disclosure, the processes 310, 312, 314, 316, 318, 320, 322, 324, 326 and 328 are performed sequentially, in order as shown. As noted above, according to one or more embodiments, processes 310, 312 and 314 may be repeated one to 10 times before proceeding to 316.

Reference throughout this specification to “one embodiment,” “certain embodiments,” “various embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in various embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein provided a description with reference to particular embodiments, it is to be understood that these embodiments are merely illustrative of the principles and applications of the disclosure. It will be apparent to those skilled in the art that various modifications and variations can be made to the present disclosure without departing from the spirit and scope thereof. Thus, it is intended that the present disclosure include modifications and variations that are within the scope of the appended claims and their equivalents.

What is claimed is:

1. An ex situ physical vapor deposition (PVD) process kit conditioning apparatus configured to condition process kit components of a PVD substrate processing chamber, the ex situ PVD process kit conditioning apparatus comprising:
a chamber assembly comprising a chamber floor, a chamber housing and a chamber upper plate, the chamber upper plate having one or more openings configured to expose one or more targets, the conditioning apparatus configured to deposit a defect reduction coating, the chamber housing and chamber upper plate defining a conditioning volume configured to receive process kit components from the PVD substrate processing chamber; and
a central cathode assembly configured to mount the one or more targets, wherein upon positioning of the process kit components within the conditioning volume of the ex situ PVD process kit conditioning apparatus, the central cathode assembly is positioned and configured so that apparatus deposit the defect reduction coating substantially uniformly on an inner surface of the process kit components of the PVD substrate processing chamber, at least one of the process kit components having a sloped wall and a concave inner surface.

2. The PVD process kit conditioning apparatus according to claim 1, wherein the central cathode assembly is positioned and configured so that apparatus deposits a substantially uniform defect reduction coating on the process kit components having a thickness that varies less than 50% over an entire inner surface of the process kit components.

3. The PVD process kit conditioning apparatus according to claim 2, wherein the entire inner surface comprises one or more of a concave inner surface of a chamber liner, a concave inner surface of a chamber lid and a concave inner surface of a rotatable shield.

4. The PVD process kit conditioning apparatus according to claim 2, wherein the process kit components comprises a chamber liner comprising a bowl-shaped body having a concave inner surface, the chamber liner positioned within the conditioning volume.

5. The PVD process kit conditioning apparatus according to claim 4, wherein the chamber liner further comprises a flange extending from an outer surface of the chamber liner, the flange in contact with the chamber floor at an inner ledge.

6. The PVD process kit conditioning apparatus according to claim 4, wherein the chamber liner further comprises an open top and an at least partially closed bottom, the at least partially closed bottom in contact with the chamber floor, the open top in contact with a chamber lid, the chamber lid positioned within the conditioning volume.

7. The PVD process kit conditioning apparatus according to claim 6, wherein the chamber lid creates a fluid tight seal with the chamber liner.

8. The PVD process kit conditioning apparatus according to claim 6, wherein the chamber lid has a linear height greater than a linear height of a rotatable shield of the PVD substrate processing chamber.

9. The PVD process kit conditioning apparatus according to claim 8, wherein the linear height of the chamber lid is 20% greater than the linear height of the rotatable shield of the PVD substrate processing chamber.

10. The PVD process kit conditioning apparatus according to claim 8, wherein the linear height of the chamber lid is at least 10% greater than the linear height of the rotatable shield of the PVD substrate processing chamber.

11. The PVD process kit conditioning apparatus according to claim 6, wherein the chamber lid comprises one or more openings aligned with the one or more openings of the chamber upper plate.

12. The PVD process kit conditioning apparatus according to claim 6, wherein the chamber lid comprises a flange positioned on an outer surface of the chamber lid, the flange in contact with the chamber upper plate.

13. The PVD process kit conditioning apparatus according to claim 2, wherein the process kit components comprise a rotatable shield having a substantially cylindrical body and an inner surface and a sidewall, the rotatable shield positioned within the conditioning volume.

14. The PVD process kit conditioning apparatus according to claim 13, wherein an outer peripheral edge of the rotatable shield is in contact with the chamber floor at an inner ledge.

15. The PVD process kit conditioning apparatus according to claim 13, further comprising an intermediate liner and a chamber lid, the intermediate liner having a cylindrical body having an open top and an open bottom, the open bottom creating a fluid tight seal with the open top of the rotatable shield, and the open top creating a fluid tight seal with the chamber lid.

16. The PVD process kit conditioning apparatus according to claim 15 wherein the rotatable shield has one or more openings positioned below the one or more targets.

17. The PVD process kit conditioning apparatus according to claim 2, wherein the process kit components further comprises an upper shield having an inner surface, a lower shield having an inner surface, a telescopic cover ring having an inner surface and an intermediate shield of a conventional PVD substrate processing chamber having an inner surface, the PVD process kit conditioning apparatus configured to deposit a defect reduction coating on an inner surface of the process kit components, having a thickness that varies less than 50%.

18. The PVD process kit conditioning apparatus according to claim 2, wherein the process kit components further comprise a lower shield positioned within an opening of the chamber floor.

19. A method of conditioning one or more process kit components of a physical vapor deposition (PVD) substrate processing chamber, the method comprising:
removing the one or more process kit components from the PVD substrate processing chamber, the one or more process kit components of the PVD substrate processing chamber including a chamber liner including an inner surface having a sloped wall and a concave inner surface and a rotatable shield including an inner surface having concave surface;
placing the one or more process kit components removed from the PVD substrate processing chamber in a separate, ex-situ PVD process kit conditioning apparatus comprising a central cathode assembly positioned and configured so that the apparatus deposits a substantially uniform defect reduction coating on the inner surface of the one or more process kit components; and
depositing a substantially uniform defect reduction coating on the inner surface of the one or more process kit components.

20. The method according to claim 19, wherein the substantially uniform defect reduction coating on the process kit components have a thickness that varies less than 50% over an entire inner surface of the process kit components.
